(19) United States
(12) Patent Application Publication
(10) Pub. No.: US 2024/0124337 A1
(43) Pub. Date: Apr. 18, 2024

(54) PH/REDOX POTENTIAL-ADJUSTED WATER PRODUCTION APPARATUS

(71) Applicant: KURITA WATER INDUSTRIES LTD., Tokyo (JP)

(72) Inventor: Nobuko GAN, Tokyo (JP)

(73) Assignee: KURITA WATER INDUSTRIES LTD., Tokyo (JP)

(21) Appl. No.: 18/020,686

(22) PCT Filed: Mar. 18, 2021
(86) PCT No.: PCT/JP2021/011276

§ 371 Date: Dec. 20, 2023

(30) Foreign Application Priority Data
Aug. 12, 2020 (JP) 2020-136213

(51) Int. Cl. C02F 1/66

(52) U.S. Cl. CPC C02F 1/66; C02F 2103/04; C02F 2209/003; C02F 2209/04; C02F 2209/06

(57) ABSTRACT

The pH/redox potential-adjusted water production apparatus includes a supply line for ultrapure water, which is provided with a platinum group metal-supporting resin column. The ultrapure water supply line is branched downstream into a first adjusted water production line and a second adjusted water production line. The first adjusted water production line communicates with a pH adjuster tank and a redox potential adjuster tank, and a first reservoir is provided downstream from them. The second adjusted water production line communicates with a pH adjuster tank and a redox potential adjuster tank, and a second reservoir is provided downstream from them. With such a pH/redox potential-adjusted water production apparatus, it is possible to dissolve a predetermined amount of wiring metal in a wiring production step for semiconductors in which a transition metal such as cobalt is used as the wiring metal.

### TECHNICAL FIELD

The present invention relates to a pH/redox potential-adjusted water production apparatus used in the field of electronic industry and the like and particularly to a production apparatus for pH/redox potential-adjusted water that can dissolve a predetermined amount of wiring metal in a wiring production step for semiconductors in which a transition metal such as cobalt is used as the wiring metal.

### BACKGROUND ART

In recent years, as the semiconductors are reduced in size, the wiring width is also being reduced. In the wiring production step in the conventional semiconductor manufacturing process, misalignment of the wiring caused by the production apparatus occurs, but the influence of misalignment of the wiring can be ignored because the wiring width is wide, and such misalignment may not affect the yield. However, as the wiring width becomes finer, even if the wiring misalignment is very small, it affects the yield and cannot be ignored. Since the reduction in width of wiring will continue in the future and the misalignment of wiring is caused by the production apparatus, it is difficult to prevent the occurrence of misalignment of wiring itself.

In this context, for a method of preventing degradation of the semiconductor performance due to the misalignment of wiring, the development of ultra-fine etching technique for wiring layers is being progressed. This ultra-fine etching technique refers to a technique for preventing short-circuiting by creating a structure in which an extremely small amount of the wiring layer is preliminarily dissolved to utilize interlayer insulating films existing between wirings as those like embankments, and even in an unlikely event of wiring misalignment, the wirings do not come into contact with each other. This technique will be needed as long as the size miniaturization advances.

In this semiconductor manufacturing process, wirings composed of a transition metal such as copper or cobalt may be adopted. For the ultra-fine etching of wirings, wet treatment is applied. For example, there is commonly used a scheme called a digital etch process in which the treatment is performed alternately with two liquids of APM (mixed solution of ammonia water and hydrogen peroxide water) and carbonated water, and oxidization and dissolution of the metal surface is repeated to gradually remove the wiring metal.

### SUMMARY OF THE INVENTION

### Problems to be Solved by the Invention

In the conventional ultra-fine etching such as digital etch, however, the amount of dissolution of metal (=depth, referred to as metal loss, hereinafter) differs depending on the difference in the wiring width (referred to as pattern loading, hereinafter), and there is a problem in that the performance of semiconductors is adversely affected even if the ultra-fine etching can be performed. There is also a problem in that the electrical characteristics of semiconductors deteriorate due to the increase in the surface roughness of the wiring metal surface after the ultra-fine etching. Specifically, in the digital etch using extremely dilute APM (e.g., ammonia concentration: 10 ppm, hydrogen peroxide concentration: 100 ppm) and carbonated water, it needs treatment time of about 20 minutes to achieve a metal loss of 10 nm, and the pattern loading occurs.

For this reason, in a step of producing wirings composed of a transition metal (e.g., cobalt), there is a demand for a liquid for ultra-fine etching that can achieve a metal loss of 10 nm in a short treatment time with a constant metal loss regardless of a difference in the size of the wiring width.

The present invention has been made in view of the above problems, and an object of the present invention is to provide a production apparatus for pH/redox potential-adjusted water that can dissolve a predetermined amount of wiring metal in a wiring production step for semiconductors in which a transition metal such as cobalt is used as the wiring metal.

### Means for Solving the Problems

In view of the above object, the present invention provides a pH/redox potential-adjusted water production apparatus that produces cleaning water having a desired pH and redox potential by adding a pH adjuster and a redox potential adjuster to ultrapure water, comprising: a hydrogen peroxide removal mechanism provided in an ultrapure water supply line; branched flow paths that are branched into two or more downstream the hydrogen peroxide removal mechanism; a pH adjusting mechanism that adds the pH adjuster and a redox potential adjusting mechanism that adds the redox potential adjuster, the pH adjusting mechanism and the redox potential adjusting mechanism being provided in each of the branched flow paths; an adjusted water quality monitoring mechanism that is provided downstream the pH adjusting mechanism and the redox potential adjusting mechanism to measure water quality of pH/redox potential-adjusted water; an additive amount control mechanism that adjusts an additive amount of the pH adjuster from the pH adjusting mechanism and an additive amount of the redox potential adjuster from the redox potential adjusting mechanism based on a measurement result of the adjusted water quality monitoring mechanism; and a reservoir that is provided for each of the branched flow paths to store the pH/redox potential-adjusted water, wherein two or more types of the pH/redox potential-adjusted water can be supplied from the branched flow paths (Invention 1).

According to the invention (Invention 1), the ultrapure water from the ultrapure water supply line is passed through the hydrogen peroxide removal mechanism to remove a trace amount of hydrogen peroxide contained in the ultrapure water, the ultrapure water from which the hydrogen peroxide has been removed is supplied to two or more branched flow paths, the pH adjuster and the redox potential adjuster are added for each of the branched flow paths so as to achieve desired pH and redox potential, then the additive amounts of the pH adjuster and the redox potential adjuster are controlled with the additive amount control mechanism so as to achieve desired pH and redox potential, thereby eliminating the influence of the dissolved hydrogen peroxide in the raw water, and two or more types of pH/redox potential-adjusted water having different pHs and/or redox potentials can be produced. This enables the cleaning with the two or more types of pH/redox potential-adjusted water having different pHs and/or redox potentials, and it is therefore possible to dissolve a predetermined amount of wiring metal in a wiring production step for semiconductors in which a transition metal such as cobalt is used as the wiring metal.

In the above invention (Invention 1), at least one of the two or more types of the pH/redox potential-adjusted water may preferably have a pH of 9 or higher and 13 or lower and a redox potential of 0 V or higher and 1.7 V or lower (Invention 2).

According to the invention (Invention 2), the pH/redox potential-adjusted water easily renders a transition metal such as cobalt nonconductive, which is less likely to dissolve, and the dissolution rate of cobalt can be suppressed to a low level.

In the above invention (Invention 1, 2), the pH adjuster may be preferably one or more of ammonia, sodium hydroxide, potassium hydroxide, TMAH, hydrochloric acid, hydrofluoric acid, citric acid, formic acid, and carbon dioxide gas, and the redox potential adjuster may be preferably one or more of hydrogen peroxide, ozone gas, and oxygen gas (Invention 3).

According to the invention (Invention 3), by appropriately selecting the pH adjuster and the redox potential adjuster and adjusting their additive amounts, various types of the pH/redox potential-adjusted water can be produced, and the treatment can therefore be performed with various combinations of the pH/redox potential-adjusted water in accordance with the wiring metal and line width of semiconductors.

In the above invention (Invention 1 to 3), the pH adjuster or the redox potential adjuster may be a liquid and preferably fed into the ultrapure water supply line by a pump or a pressurizing means that uses a closed tank and an inert gas (Invention 4). Additionally or alternatively, in the above invention (Inventions 1 to 3), the pH adjuster or the redox potential adjuster may be a gas and preferably added by gas dissolution using a direct gas-liquid contactor with a gas-permeable membrane module or an ejector (Invention 5).

According to the invention (Invention 4, 5), the additive amounts of the pH adjuster and the redox potential adjuster can be easily and finely controlled.

In the above invention (Invention 1 to 5), the reservoir for the pH/redox potential-adjusted water may preferably have an inert gas supply mechanism (Invention 6).

According to the invention (Invention 6), it is possible to prevent oxygen and carbon dioxide gas from dissolving in the obtained pH/redox potential-adjusted water while it is stored; therefore, an increase in the dissolved oxygen concentration can be prevented, and fluctuations in the pH and the like can be suppressed.

In the above invention (Invention 1 to 6), the pH/redox potential-adjusted water may be preferably for cleaning a surface of a semiconductor material on which a transition metal is partially or entirely exposed (Invention 7).

According to the invention (invention 7), the cleaning may be alternately performed with the pH and redox potential-adjusted water capable of suppressing the dissolution of a transition metal such as cobalt and different pH and redox potential-adjusted water capable of finely adjusting the dissolution of the transition metal in accordance with the type of the transition metal, thereby enabling the ultra-fine etching treatment with a metal loss of 10 nm as a constant metal loss in a short treatment time regardless of a difference in the wiring width.

### Advantageous Effect of the Invention

According to the pH/redox potential-adjusted water production apparatus of the present invention, two or more types of pH/redox potential-adjusted water having different pHs and/or redox potentials can be produced; therefore, by combining these different types of the pH/redox potential-adjusted water, the cleaning can be alternately performed with the cleaning water having the pH and redox potential capable of suppressing the dissolution of a transition metal such as cobalt and different cleaning water having the pH and redox potential capable of finely adjusting the dissolution of the transition metal, and it is possible to dissolve a predetermined amount of wiring metal in a wiring production step for semiconductors in which a transition metal such as cobalt is used as the wiring metal. This enables the ultra-fine etching treatment with a metal loss, for example, of 10 nm or the like as a constant metal loss in a short treatment time regardless of a difference in the size of wiring width.

### BRIEF DESCRIPTION OF DRAWINGS

FIG. 1 is a schematic diagram illustrating an adjusted water production apparatus according to a first embodiment of the present invention.

FIG. 2 is a schematic diagram illustrating an adjusted water production apparatus according to a second embodiment of the present invention.

FIG. 3 is a schematic diagram illustrating an adjusted water production apparatus according to a third embodiment of the present invention.

FIG. 4 is a schematic diagram illustrating an adjusted water production apparatus according to a fourth embodiment of the present invention.

FIG. 5 is a graph illustrating the relationship between the wiring width and the metal loss of cobalt in Examples 1 to 3.

FIG. 6 is a graph illustrating the relationship between the wiring width and the metal loss of cobalt in Examples 4 to 6.

FIG. 7 is a graph illustrating the relationship between the wiring width and the metal loss of cobalt in Examples 7 to 9.

### EMBODIMENTS FOR CARRYING OUT THE INVENTION

Hereinafter, the pH/redox potential-adjusted water production apparatus of the present invention will be described in detail based on each embodiment with reference to the accompanying drawings.

### First Embodiment

<pH/Redox Potential-Adjusted Water Production Apparatus>

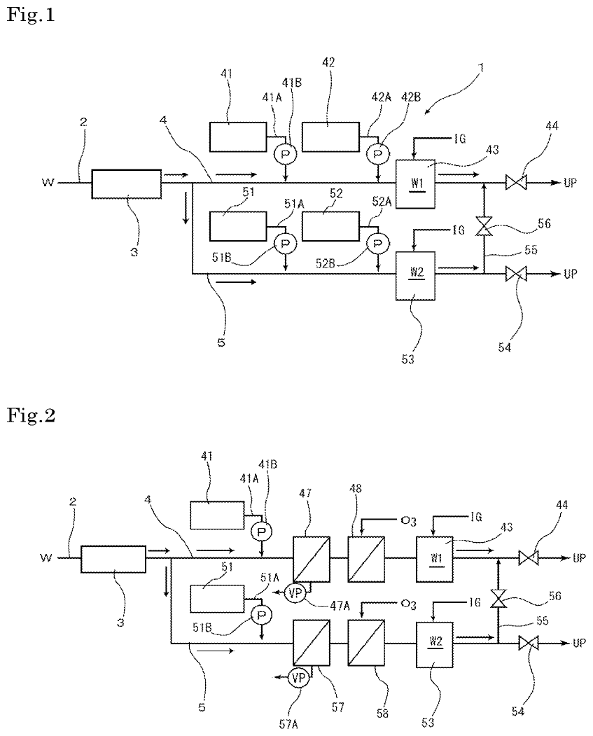

FIG. 1 illustrates a pH/redox potential-adjusted water production apparatus according to a first embodiment of the present invention. In FIG. 1, a pH/redox potential-adjusted water production apparatus 1 includes a supply line 2 for ultrapure water W, which is provided with a platinum group metal-supporting resin column 3 as a hydrogen peroxide removal mechanism. The ultrapure water supply line 2 is blanched downstream the platinum group metal-supporting resin column 3 into a first adjusted water production line 4 and a second adjusted water production line 5.

The first adjusted water production line 4 is provided with a pH adjuster feeding line 41A and a redox potential adjuster feeding line 42A that merge into the first adjusted water production line 4. The pH adjuster feeding line 41A includes a liquid supply mechanism 41B that communicates with a pH adjuster tank 41. The redox potential adjuster feeding line 42A includes a liquid supply mechanism 42B that communicates with a redox potential adjuster tank 42. Downstream of the redox potential adjuster feeding line 42A is provided with a first reservoir 43 that stores first pH/redox potential-adjusted water. In the present embodiment, the first reservoir 43 is purged with an inert gas IG. The first adjusted water production line 4 extends from the first reservoir 43 to a use point UP. Reference numeral 44 denotes an on-off valve of the first adjusted water production line 4 heading to the use point UP.

Likewise, the second adjusted water production line 5 is provided with a pH adjuster feeding line 51A and a redox potential adjuster feeding line 52A that merge into the second adjusted water production line 5. The pH adjuster feeding line 51A includes a liquid supply mechanism 51B that communicates with a pH adjuster tank 51. The redox potential adjuster feeding line 52A includes a liquid supply mechanism 52B that communicates with a redox potential adjuster tank 52. Downstream of the redox potential adjuster feeding line 52A is provided with a second reservoir 53 that stores second pH/redox potential-adjusted water. In the present embodiment, the second reservoir 53 is purged with an inert gas IG. The second adjusted water production line 5 extends from the second reservoir 53 to a use point UP. Reference numeral 54 denotes an on-off valve of the second adjusted water production line 5 heading to the use point UP, reference numeral 55 denotes a bypass line that connects the first adjusted water production line 4 and the second adjusted water production line 5, and reference numeral 56 denotes an on-off valve of the bypass line.

In the present embodiment, the downstream side of the pH adjuster feeding line 41A and redox potential adjuster feeding line 42A of the first adjusted water production line 4, for example, the reservoir 43, and the downstream side of the pH adjuster feeding line 51A and redox potential adjuster feeding line 52A of the second adjusted water production line 5, for example, the reservoir 53, are provided with respective adjusted water quality monitoring mechanisms that may each include a pH meter as pH measuring means (not illustrated), an ORP meter as redox potential measuring means (not illustrated), etc. These pH meters and ORP meters are connected to a control device such as a personal computer. This control device can control the feeding amount of the pH adjuster and the feeding amount of the redox potential adjuster based on the measured values of the pH meters and the ORP meters.

### <Ultrapure Water>

In the present embodiment, preferred properties of the ultrapure water W as the raw water may be, for example, resistivity: 18.1 MΩ·cm or more, fine particles: 1000 particles/L or less with a particle diameter of 50 nm or more, viable bacteria: 1 bacterium/L or less, TOC (Total Organic Carbon): 1 μg/L or less, total silicon: 0.1 μg/L or less, metals: 1 ng/L or less, ions: 10 ng/L or less, hydrogen peroxide; 30 μg/L or less, and water temperature: 25±2° C.

### <Hydrogen Peroxide Removal Mechanism>

In the present embodiment, the platinum group metal-supporting resin column 3 is used as the hydrogen peroxide removal mechanism.

### (Platinum Group Metal)

In the present embodiment, examples of the platinum group metal supported on the platinum group metal-supporting resin used in the platinum group metal-supporting resin column 3 include ruthenium, rhodium, palladium, osmium, iridium, and platinum. One type of these platinum group metals can be used alone, two or more types can be used in combination, one or more alloys of two or more types can be used, or a refined product of mixture produced naturally can be used without being separated into a single body. Among these, one type or a mixture of two or more types of platinum, palladium, and platinum/palladium alloy can be preferably used because of strong catalytic activity. Nano-order fine particles of these metals can be particularly preferably used.

### (Carrier Resin)

In the platinum group metal-supporting resin column 3, any of ion exchange resins can be used as the carrier resin for supporting the platinum group metal. Among these, an anion exchange resin can be used particularly preferably. A platinum-based metal is negatively charged, so it is stably supported on the anion exchange resin and is less likely to be removed. The exchange groups of the anion exchange resin may be preferably in the OH form. The OH-type anion exchange resin has an alkaline resin surface, which promotes the decomposition of hydrogen peroxide.

### <pH Adjuster Feeding Device>

In the present embodiment, the pH adjuster feeding device is not particularly limited, and a general chemical feeding device can be used. When the pH adjuster is a liquid, a pump such as a diaphragm pump can be used, and it may be desired to purge the inside of the pH adjuster tanks 41 and 51 with an inert gas or provide a mechanism for removing dissolved oxygen in the pH adjuster liquid in the tanks using a degassing membrane. Additionally or alternatively, a pressurization pump can also be preferably used, which is configured such that a closed container is filled with the pH adjuster or the redox potential adjuster together with an inert gas such as N₂ gas and the adjuster is pushed out by the pressure of the inert gas. On the other hand, when the pH adjuster is a gas, a direct gas-liquid contactor such as a gas-permeable membrane module or an ejector can be used.

### <pH Adjuster>

In the present embodiment, the pH adjuster to be fed from the pH adjuster tanks 41 and 51 is not particularly limited, and when adjusting the pH to lower than 7, a liquid such as citric acid, formic acid, or hydrochloric acid or a gas such as CO₂ can be used, but in the present embodiment, a liquid may be used. When adjusting the pH to 7 or higher, ammonia, sodium hydroxide, potassium hydroxide, TMAH, or the like can be used. When the pH/redox potential-adjusted water is used as cleaning water for wafers on which a transition metal such as copper or cobalt is exposed, it may be preferred to make the cleaning water alkaline, but alkali metal solutions such as sodium hydroxide solution may not be suitable because they contain metal components. In the present embodiment, therefore, it may be most preferred to use ammonia, citric acid, or the like.

### <Redox Potential Adjuster Feeding Device>

In the present embodiment, the redox potential adjuster feeding device is not particularly limited, and a general chemical feeding device can be used. When the redox potential adjuster is a liquid, a pump such as a diaphragm pump can be used, and it may be desired to purge the inside of the redox potential adjuster tanks 42 and 52 with an inert gas or provide a mechanism for removing dissolved oxygen in the redox potential adjuster liquid in the tanks using a degassing membrane. Additionally or alternatively, a pressurization pump can also be preferably used, which is configured such that a closed container is filled with the redox potential adjuster together with an inert gas such as N₂ gas and the adjuster is pushed out by the pressure of the inert gas. On the other hand, when the redox potential adjuster is a gas, a direct gas-liquid contactor such as a gas-permeable membrane module or an ejector can be used.

### <Redox Potential Adjuster>

In the present embodiment, the redox potential adjuster to be fed from the redox potential adjuster tanks 42 and 52 is not particularly limited, but in order to adjust the redox potential to the positive side, a liquid such as hydrogen peroxide water or a gas such as ozone gas or oxygen gas can be used. On the other hand, in order to adjust the redox potential to the negative side, a liquid such as oxalic acid or a gas such as hydrogen can be used. In the present embodiment, a liquid may be used. When the pH/redox potential-adjusted water is used, for example, as cleaning water for wafers on which a transition metal such as copper or cobalt is exposed, it is preferred to adjust the redox potential to be positive in order to suppress the dissolution of these materials, so it may be most preferred to use hydrogen peroxide water.

<Method of Producing pH/Redox Potential-Adjusted Water>

The description will now be made below for a method of producing pH/redox potential-adjusted water using the pH/redox potential-adjusted water production apparatus 1 of the present embodiment having the configuration as described previously.

(Method of Producing First pH/Redox Potential-Adjusted Water)

The ultrapure water W as the raw water generally contains several tens of ppb level of hydrogen peroxide, so in order to accurately control the redox potential of the cleaning liquid, hydrogen oxide in the ultrapure water W has to be preliminarily removed. To this end, first, the ultrapure water W is supplied from the supply line 2 to the platinum group metal-supporting resin column 3. The platinum group metal-supporting resin column 3 uses the catalytic action of the platinum group metal to decompose and remove hydrogen peroxide in the ultrapure water W, that is, serves as a hydrogen peroxide removal mechanism. After that, the ultrapure water W is branched into the first adjusted water production line 4 and the second adjusted water production line 5.

Then, in the first adjusted water production line 4, the pH adjuster is fed from the pH adjuster tank 41. The addition of the pH adjuster may be appropriately set in accordance with the desired pH, the flow rate in the first adjusted water production line 4, and the concentration of the pH adjuster. When making the cleaning water alkaline upon cleaning of semiconductors having fine lines of a transition metal, for example, the pH adjuster may be added in an amount such that the pH of the cleaning liquid is within a range of 9 to 13. When making the cleaning water acidic, the pH adjuster may be added in an amount such that the pH of the cleaning liquid is within a range of 0 to 3.5.

Then, the redox potential adjuster is fed from the redox potential adjuster tank 42. The addition of the redox potential adjuster may be appropriately set in accordance with the desired redox potential, the flow rate in the first adjusted water production line 4, and the concentration of the redox potential adjuster. For cleaning semiconductors having fine lines of a transition metal, the redox potential adjuster may be added in an amount such that the redox potential of the cleaning liquid is within a range of 0 to 1.7 V.

After first pH/redox potential-adjusted water W1 is thus produced, it is stored in the first reservoir 43. Since the first reservoir 43 is purged with an inert gas, it is possible to prevent the pH or the redox potential from fluctuating due to dissolution of oxygen or carbon dioxide gas into the obtained first pH/redox potential-adjusted water W1 while it is stored. In this operation, on the basis of the measurement results of the pH meter and ORP meter (not illustrated), the control device can control the additive amount of the pH adjuster from the pH adjuster tank 41 and the additive amount of the redox potential adjuster from the redox potential adjuster tank 42, thereby stably supplying the first pH/redox potential-adjusted water W1 having the desired pH and redox potential.

(Method of Producing Second pH/Redox Potential-Adjusted Water)

On the other hand, the ultrapure water branched to the second adjusted water production line 5 can be used to produce second pH/redox potential-adjusted water W2 in the same manner as in the case of the first pH/redox potential-adjusted water W1 through feeding the pH adjuster from the pH adjuster tank 51 and further feeding the redox potential adjuster from the redox potential adjuster tank 52. In this operation, on the basis of the measurement results of the pH meter and ORP meter (not illustrated), the control device can control the additive amount of the pH adjuster from the pH adjuster tank 51 and the additive amount of the redox potential adjuster from the redox potential adjuster tank 52, thereby stably supplying the second pH/redox potential-adjusted water W2 having the desired pH and redox potential.

Then, the first pH/redox potential-adjusted water W1 and second pH/redox potential-adjusted water W2 thus produced are sent to respective use points UPs. In the present embodiment, both the adjusted water W1 and the adjusted water W2 may have different water qualities. In the second adjusted water production line 5, addition from either the pH adjuster tank 51 or the redox potential adjuster tank 52 may be omitted. If necessary, by opening the bypass line 5, both can be mixed and used.

(Example of Supplying pH/Redox Potential-Adjusted Water)

The description will then be made below for the methods of producing the above-described first pH/redox potential-adjusted water W1 and second pH/redox potential-adjusted water W2 in an exemplary case of performing an ultra-fine etching process for wirings made of cobalt, which is a transition metal.

A scheme called digital etch is used for ultra-fine etching of wirings composed of a transition metal (cobalt). This is a scheme of repeating oxidization of the metal surface and dissolution of the oxide film to dissolve the metal in a stepwise manner. When the digital etch is used for the ultra-fine etching of cobalt as a transition metal, it is necessary to form, in a first step, an oxide film on the surface of cobalt without dissolving cobalt and to dissolve, in a second step, only the metal oxide film, which has been formed in the first step, without dissolving cobalt.

According to the Pourbaix diagram, which shows which state of chemical species of a metal is most stable in aqueous solution under a given [potential-pH] condition, cobalt as a transition metal becomes passivated and is less likely to dissolve under an alkaline condition, particularly within a region in which the pH is 9 to 13. In particular, addition of about 10 to 100 ppm of hydrogen peroxide to an alkaline solution of pH 9 to 13 minimizes the dissolution rate of cobalt. It is known, however, that when the concentration of hydrogen peroxide is 1000 ppm or more, the dissolution rate of cobalt is about 30 times higher than that when hydrogen peroxide is not added. Therefore, in order to oxidize the surface of cobalt while preventing its dissolution in the first step of digital etch, it is necessary to more strictly control the pH and redox potential of APM (mixed solution of ammonia water and hydrogen peroxide water).

On the other hand, under an acidic condition, the behavior of dissolution/passivation differs depending on the difference in pH and redox potential of the aqueous solution according to the Pourbaix diagram. In order to subject a predetermined amount of cobalt to ultra-fine etching within a given time, the removal rate of the cobalt oxide film may have to be accelerated in the second step, for which the pH of the treatment liquid needs to be lower than 5.

In view of these, to subject a predetermined amount of cobalt to ultra-fine etching within a given time while suppressing the occurrence of pattern loading, the cleaning of the first step may be performed through adjusting the first pH/redox potential-adjusted water W1 composed of a mixed solution of ammonia water and hydrogen peroxide water so as to achieve the pH and redox potential at which the dissolution of the transition metal (cobalt) is the least likely to occur, that is, to achieve the pH within a range of 9 to 13 and the redox potential within a range of 0 to 1.7 V (hydrogen peroxide is about 10 to 100 ppm), and supplying the first pH/redox potential-adjusted water W1 from the first adjusted water production line 4 to the use point UP. This allows the oxide film to be formed on the cobalt surface without dissolving the cobalt. In this operation, the on-off valve 54 of the second adjusted water production line 5 is closed.

Then, to subject a predetermined amount of cobalt to ultra-fine etching within a given time, the second pH/redox potential-adjusted water W2 may be adjusted by adding citric acid, formic acid, or the like so that the pH of the treatment liquid becomes lower than 5 in order to accelerate the removal rate of the cobalt oxide film. The cleaning in the second step may then be performed through closing the on-off valve 44 of the first adjusted water production line 4 to stop the supply of the first pH/redox potential-adjusted water W1 and opening the on-off valve 54 of the second adjusted water production line 5 to supply the second pH/redox potential-adjusted water W2 from the second adjusted water production line 5 to the use point UP. This allows the predetermined amount of cobalt to undergo the ultra-fine etching.

Thus, cobalt wirings of semiconductors can be efficiently subjected to the ultra-fine etching in a short time.

### Second Embodiment

<pH/Redox Potential-Adjusted Water Production Apparatus>

FIG. 2 illustrates a pH/redox potential-adjusted water production apparatus according to a second embodiment of the present invention. The same configurations as those in the previously described first embodiment are denoted with the same reference numerals, and the detailed description will be omitted.

In FIG. 2, the pH/redox potential-adjusted water production apparatus 1 includes a first degassing membrane device 47 with a vacuum pump 47A downstream the pH adjuster tank 41 of the first adjusted water production line 4 and has a first gas dissolving membrane device 48 as substitute for the redox potential adjuster tank 42, the redox potential adjuster feeding line 42A, and the liquid supply mechanism 42B which serve as the redox potential adjusting mechanism. In the present embodiment, the first gas dissolving membrane device 48 dissolves ozone as the redox potential adjuster. In addition, the pH/redox potential-adjusted water production apparatus 1 includes a second degassing membrane device 57 with a vacuum pump 57A downstream the pH adjuster tank 51 of the second adjusted water production line 5 and has a second gas dissolving membrane device 58 that dissolves ozone as substitute for the redox potential adjuster tank 52, the redox potential adjuster feeding line 52A, and the liquid supply mechanism 52B which serve as the redox potential adjusting mechanism.

<Method of Producing pH/Redox Potential-Adjusted Water>

The description will now be made below for a method of producing pH/redox potential-adjusted water using the pH/redox potential-adjusted water production apparatus of the present embodiment having the configuration as described previously.

(Method of Producing First pH/Redox Potential-Adjusted Water)

The ultrapure water W as the raw water generally contains several tens of ppb level of hydrogen peroxide, so in order to accurately control the redox potential of the cleaning liquid, hydrogen oxide in the ultrapure water W has to be preliminarily removed. To this end, first, the ultrapure water W is supplied from the supply line 2 to the platinum group metal-supporting resin column 3. The platinum group metal-supporting resin column 3 uses the catalytic action of the platinum group metal to decompose and remove hydrogen peroxide in the ultrapure water W, that is, serves as a hydrogen peroxide removal mechanism. After that, the ultrapure water W is branched into the first adjusted water production line 4 and the second adjusted water production line 5.

Then, in the first adjusted water production line 4, the pH adjuster is fed from the pH adjuster tank 41. The addition of the pH adjuster may be appropriately set in accordance with the desired pH, the flow rate in the first adjusted water production line 4, and the concentration of the pH adjuster. When making the cleaning water alkaline upon cleaning of semiconductors having fine lines of a transition metal, for example, the pH adjuster may be added in an amount such that the pH of the cleaning liquid is within a range of 9 to 13. When making the cleaning water acidic, the pH adjuster may be added in an amount such that the pH of the cleaning liquid is within a range of 0 to 3.5.

Then, the ultrapure water W after the pH adjustment is degassed with the first degassing membrane device 47. This operation can remove the dissolved gases such as dissolved oxygen in the ultrapure water W. Subsequently, the ozone gas is dissolved in the first gas dissolving membrane device 48. In this operation, the ultrapure water W after pH adjustment is degassed, and the ozone gas can therefore be efficiently dissolved. Through this operation, the redox potential of the ultrapure water W can be adjusted to be positive.

After the first pH/redox potential-adjusted water W1 is thus produced, it is stored in the first reservoir 43. Since the first reservoir 43 is purged with an inert gas, it is possible to prevent the pH or the redox potential from fluctuating due to dissolution of oxygen or carbon dioxide gas into the obtained first pH/redox potential-adjusted water W1 while it is stored.

(Method of Producing Second pH/Redox Potential-Adjusted Water)

On the other hand, the ultrapure water branched to the second adjusted water production line 5 can be used to produce the second pH/redox potential-adjusted water W2 in the same manner as in the case of the first pH/redox potential-adjusted water W1 through feeding the pH adjuster from the pH adjuster tank 51, performing the degassing with the second degassing membrane device 57, and subsequently dissolving the ozone gas in the second gas dissolving membrane device 58.

### Third Embodiment

<pH/Redox Potential-Adjusted Water Production Apparatus>

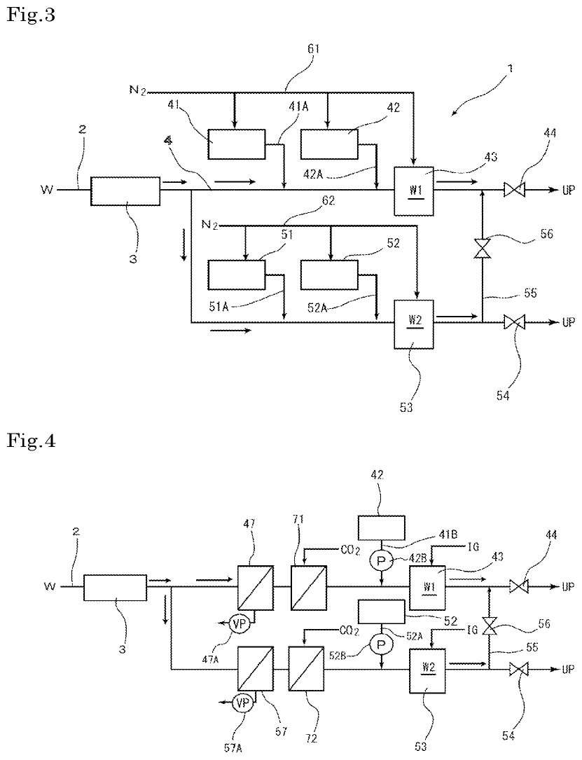

FIG. 3 illustrates a pH/redox potential-adjusted water production apparatus according to a third embodiment of the present invention. The same configurations as those in the previously described first embodiment are denoted with the same reference numerals, and the detailed description will be omitted.

In FIG. 3, the pH/redox potential-adjusted water production apparatus 1 has, as substitute for the liquid supply mechanisms 41B and 42B of the first embodiment, a configuration in which N₂ gas that is an inert gas is supplied through a gas supply pipe 61 to the pH adjuster tank 41 and the redox potential adjuster tank 42 thereby to push out the pH adjuster and the redox potential adjuster, respectively, and the N₂ gas is also supplied to the first reservoir 43 as a purge gas. The pH/redox potential-adjusted water production apparatus 1 likewise has, as substitute for the liquid supply mechanisms 51B and 52B, a configuration in which N₂ gas that is an inert gas is supplied through a gas supply pipe 62 to the pH adjuster tank 51 and the redox potential adjuster tank 52 thereby to push out the pH adjuster and the redox potential adjuster, respectively, and the N₂ gas is also supplied to the second reservoir 53 as a purge gas.

<Method of Producing pH/Redox Potential-Adjusted Water>

Also through the method of producing pH/redox potential-adjusted water using the pH/redox potential-adjusted water production apparatus of the present embodiment having the configuration as described previously, the first pH/redox potential-adjusted water W1 and the second pH/redox potential-adjusted water W2 can be produced as in the first embodiment. In particular, the present embodiment has a configuration in which the pH adjuster and the redox potential adjuster are pushed out from respective tanks by N₂ gas, and it is therefore possible to finely control the supply amounts of the pH adjuster and the redox potential adjuster.

### Fourth Embodiment

<pH/Redox Potential-Adjusted Water Production Apparatus>

FIG. 4 illustrates a pH/redox potential-adjusted water production apparatus according to a fourth embodiment of the present invention. The same configurations as those in the previously described first embodiment are denoted with the same reference numerals, and the detailed description will be omitted.

In FIG. 4, the pH/redox potential-adjusted water production apparatus 1 includes the first degassing membrane device 47 having the vacuum pump 47A in the first adjusted water production line 4 and has a first gas dissolving membrane device 71 as substitute for the pH adjuster tank 41, the pH adjuster feeding line 41A, and the liquid supply mechanism 41B which serve as the pH adjusting mechanism. In the present embodiment, the first gas dissolving membrane device 71 dissolves CO₂ as the pH adjuster. In addition, the pH/redox potential-adjusted water production apparatus 1 includes the second degassing membrane device 57 having the vacuum pump 57A in the second adjusted water production line 5 and has a second gas dissolving membrane device 72 as substitute for the pH adjuster tank 51, the pH adjuster feeding line 52A, and the liquid supply mechanism 52B which serve as the pH adjusting mechanism. The second gas dissolving membrane device 72 dissolves CO₂ as the pH adjuster.

<Method of Producing pH/Redox Potential-Adjusted Water>

The description will now be made below for a method of producing pH/redox potential-adjusted water using the pH/redox potential-adjusted water production apparatus of the present embodiment having the configuration as described previously.

(Method of Producing First pH/Redox Potential-Adjusted Water)

The ultrapure water W as the raw water generally contains several tens of ppb level of hydrogen peroxide, so in order to accurately control the redox potential of the cleaning liquid, hydrogen oxide in the ultrapure water W has to be preliminarily removed. To this end, first, the ultrapure water W is supplied from the supply line 2 to the platinum group metal-supporting resin column 3. The platinum group metal-supporting resin column 3 uses the catalytic action of the platinum group metal to decompose and remove hydrogen peroxide in the ultrapure water W, that is, serves as a hydrogen peroxide removal mechanism. After that, the ultrapure water W is branched into the first adjusted water production line 4 and the second adjusted water production line 5.

Then, in the first adjusted water production line 4, the ultrapure water W is degassed with the first degassing membrane device 47. This operation can remove the dissolved gases such as dissolved oxygen in the ultrapure water W. Subsequently, the CO₂ gas is dissolved in the first gas dissolving membrane device 71. In this operation, the ultrapure water W is degassed, and the CO₂ gas can therefore be efficiently dissolved. Through this operation, the redox potential of the ultrapure water W can be adjusted to be acidic.

Then, the redox potential adjuster is fed from the redox potential adjuster tank 42. The addition of the redox potential adjuster may be appropriately set in accordance with the desired redox potential, the flow rate in the first adjusted water production line 4, and the concentration of the redox potential adjuster. For cleaning semiconductors having fine lines of a transition metal, the redox potential adjuster may be added in an amount such that the redox potential of the cleaning liquid is within a range of 0 to 1.7 V.

After the first pH/redox potential-adjusted water W1 is thus produced, it is stored in the first reservoir 43. Since the first reservoir 43 is purged with an inert gas, it is possible to prevent the pH or the redox potential from fluctuating due to dissolution of oxygen or carbon dioxide gas into the obtained first pH/redox potential-adjusted water W1 while it is stored.

(Method of Producing Second pH/Redox Potential-Adjusted Water)

On the other hand, the ultrapure water branched to the second adjusted water production line 5 can be used to produce the second pH/redox potential-adjusted water W2 in the same manner as in the case of the first pH/redox potential-adjusted water W1 through performing the degassing with the second degassing membrane device 57, dissolving the CO₂ gas in the second gas dissolving membrane device 72, and subsequently feeding the redox potential adjuster from the redox potential adjuster tank 52.

While the pH/redox potential-adjusted water production apparatus of the present invention has been described with reference to the accompanying drawings, the present invention is not limited to the above-described embodiments, and various modifications are possible. For example, in the third embodiment, the redox potential may be adjusted in the negative direction by dissolving hydrogen gas instead of ozone gas. Additionally or alternatively, the apparatus may be configured by arbitrarily combining the configurations of the first adjusted water production line 4 and the second adjusted water production line 5 of the apparatuses illustrated in FIGS. 1 to 4. Additionally or alternatively, there may be further provided a mechanism for removing dissolved oxygen in the first pH/redox potential-adjusted water W1 and the second pH/redox potential-adjusted water W2 which have been adjusted.

### EXAMPLES

The present invention will be described in more detail with the following specific examples.

### Examples 1 and 2

### (Preparation of Treatment Liquid 1)

The pH/redox potential-adjusted water production apparatus was configured based on the apparatus illustrated in FIG. 1 by providing the second adjusted water production line 5 with the second degassing membrane device 57 having the vacuum pump 57A and second gas dissolving membrane device 72 for dissolving CO₂ gas as illustrated in FIG. 4.

The above apparatus was used to add ammonia from the pH adjuster tank 41 and hydrogen peroxide water from the redox potential adjuster tank 42 to the ultrapure water W in the first adjusted water production line 4 to produce extremely dilute APM (ammonia concentration: 10 ppm (pH about 10), hydrogen peroxide concentration: 100 ppm (redox potential: 0.05 V)) as the first pH/redox potential-adjusted water W1. The above apparatus was also used to dissolve CO₂ gas from the second gas dissolving membrane device 72 in the second adjusted water production line 5 to produce carbonated water (carbon dioxide gas concentration: ppm (pH 5.5)) as the second pH/redox potential-adjusted water W2. The first pH/redox potential-adjusted water W1 and the second pH/redox potential-adjusted water W2 were each used as treatment liquid 1.

### (Digital Etch Treatment Test)

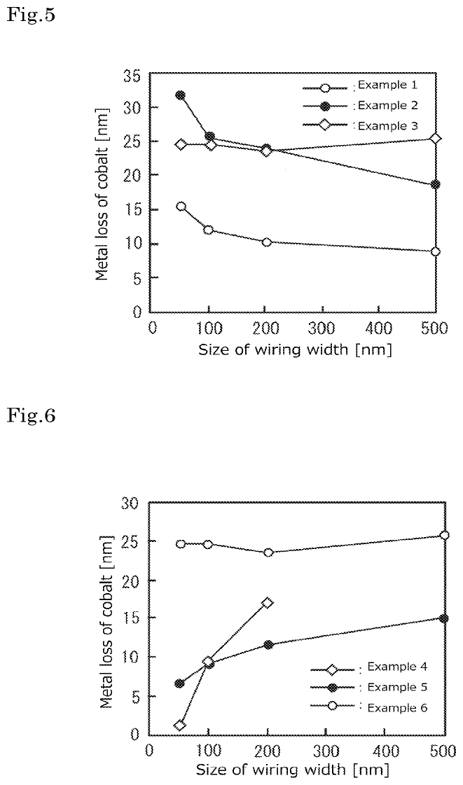

A CVD/ECD Co pattern wafer (wiring width: 50 to 500 nm, 300 mmΦ) cut into 30 mm×30 mm was used as a test piece, and the cycle of immersing the test piece in the first pH/redox potential-adjusted water W1 for 1 minute and in the second pH/redox potential-adjusted water W2 for 1 minute was repeated 5 times (Example 1) and 10 times (Example 2). After that, the wiring portion of the Co pattern wafer was observed with XSEM, and the metal loss of cobalt was measured. The results are illustrated in FIG. 5.

### Example 3

### (Preparation of Treatment Liquid 2)

The apparatus illustrated in FIG. 1 was used to add ammonia from the pH adjuster tank 41 and hydrogen peroxide water from the redox potential adjuster tank 42 to the ultrapure water W in the first adjusted water production line 4 to produce extremely dilute APM (ammonia concentration: 10 ppm (pH about 10), hydrogen peroxide concentration: 100 ppm (redox potential: 0.05 V)) as the first pH/redox potential-adjusted water W1. The apparatus illustrated in FIG. 1 was also used to add citric acid from the pH adjuster tank 41 in the second adjusted water production line 5 to produce citric acid-dissolved water (citric acid concentration: 5 mM (pH 2.8)) as the second pH/redox potential-adjusted water W2. The first pH/redox potential-adjusted water W1 and the second pH/redox potential-adjusted water W2 were each used as treatment liquid 2.

### (Digital Etch Treatment Test)

Using the treatment liquid 2, the cycle of immersing the test piece in the first pH/redox potential-adjusted water W1 for 1 minute and in the second pH/redox potential-adjusted water W2 for 1 minute, as in Example 1, was repeated 5 times (Example 3). After that, the wiring portion of the Co pattern wafer was observed with XSEM, and the metal loss of cobalt was measured. The results are also illustrated in FIG. 5.

As apparent from FIG. 5, in Examples 1 and 2 using the treatment liquid 1 in which the second pH/redox potential-adjusted water W2 was conventional carbonated water, the treatment time in the first pH/redox potential-adjusted water W1 and the treatment time in the second pH/redox potential-adjusted water W2 were each 1 minute, so, in Example 1, the metal loss was about 12 nm/10 minutes for a total treatment time of 10 minutes, while in Example 2, the metal loss was about 25 nm/20 minutes for a total treatment time of 20 minutes. In Examples 1 and 2, it can be found that it is difficult to achieve a metal loss of cobalt of 10 nm/5 minutes, which is generally required for ultra-fine etching. It can also be found that the metal loss of cobalt differs depending on the difference in wiring width and the pattern loading occurs.

On the other hand, in Example 3 in which the second pH/redox potential-adjusted water W2 was changed from the conventional carbonated water to 5 mM citric acid-dissolved water, the metal loss of cobalt when repeating 5 times the digital etch treatment is about 25 nm/10 minutes as an average, and it can be expected that a metal loss of cobalt of 10 nm/5 minutes can be achieved by changing the number of repetitions to twice. It can also be found that there is almost no difference in the metal loss of cobalt due to the difference in wiring width and no pattern loading occurs.

### Examples 4 to 6

### (Preparation of Treatment Liquid 3)

The apparatus illustrated in FIG. 1 was used to add ammonia from the pH adjuster tank 41 and hydrogen peroxide water from the redox potential adjuster tank 42 to the ultrapure water W in the first adjusted water production line 4 to produce extremely dilute APM (ammonia concentration: 10 ppm, hydrogen peroxide concentration: 100 ppm) as the first pH/redox potential-adjusted water W1. The apparatus illustrated in FIG. 1 was also used to add a predetermined citric acid from the pH adjuster tank 41 in the second adjusted water production line 5 to produce citric acid-dissolved water (citric acid concentration 0.0005 mM: Example 4, 0.05 mM: Example 5, 5 mM (pH 2.8): Example 6) as the second pH/redox potential-adjusted water W2. The first pH/redox potential-adjusted water W1 and the second pH/redox potential-adjusted water W2 were each used as treatment liquid 3.

### (Digital Etch Treatment Test)

Using the treatment liquid 3, the cycle of immersing the test piece in the first pH/redox potential-adjusted water W1 for 1 minute and in the second pH/redox potential-adjusted water W2 for 1 minute, as in Example 1, was repeated 5 times. After that, the wiring portion of the Co pattern wafer was observed with XSEM, and the metal loss of cobalt was measured. The results are illustrated in FIG. 6.

As apparent from FIG. 6, when the metal loss of cobalt due to the second pH/redox potential-adjusted water W2 depending on differences in the citric acid concentration was checked, the metal loss in Example 4 was 9 nm/10 minutes as an average, the metal loss in Example 5 was 10 nm/10 minutes as an average, and the metal loss in Example 6 was 25 nm/10 minutes as a average. In Examples 4 and 5, the metal loss of cobalt differed depending on differences in the line width, but in Example 6, there was almost no change in the metal loss of cobalt due to differences in the line width. From these facts, it can be expected that the citric acid-dissolved water having a citric acid concentration of 5 mM or more is effective in achieving a metal loss of cobalt of 10 nm/5 minutes, which is generally required for ultra-fine etching, without causing pattern loading.

### Examples 7 to 9

### (Preparation of Treatment Liquid 4)

The apparatus illustrated in FIG. 1 was used to add ammonia from the pH adjuster tank 41 and hydrogen peroxide water from the redox potential adjuster tank 42 to the ultrapure water W in the first adjusted water production line 4 to produce extremely dilute APM (ammonia concentration: 10 ppm, hydrogen peroxide concentration: 100 ppm) as the first pH/redox potential-adjusted water W1. The apparatus illustrated in FIG. 1 was also used to add a predetermined amount of citric acid from the pH adjuster tank 41 in the second adjusted water production line 5 to produce citric acid-dissolved water (citric acid concentration 5 mM (pH 2.8): Example 7) as the second pH/redox potential-adjusted water W2. The first pH/redox potential-adjusted water W1 and the second pH/redox potential-adjusted water W2 were each used as treatment liquid 4.

### (Preparation of Treatment Liquid 5)

Using the same first pH/redox potential-adjusted water W1 as in the treatment liquid 4, formic acid-dissolved water (formic acid concentration 0.05 mM (pH 4.4): Example 8) was produced as the second pH/redox potential-adjusted water W2 by adding formic acid from the pH adjuster tank 41 in the second adjusted water production line 5. The first pH/redox potential-adjusted water W1 and the second pH/redox potential-adjusted water W2 were each used as treatment liquid 5.

### (Preparation of Treatment Liquid 6)

Using the same first pH/redox potential-adjusted water W1 as in the treatment liquid 4, formic acid-dissolved water (formic acid concentration 5 mM (pH 3.1): Example 9) was produced as the second pH/redox potential-adjusted water W2 by adding formic acid from the pH adjuster tank 41 in the second adjusted water production line 5. The first pH/redox potential-adjusted water W1 and the second pH/redox potential-adjusted water W2 were each used as treatment liquid 6.

### (Digital Etch Treatment Test)

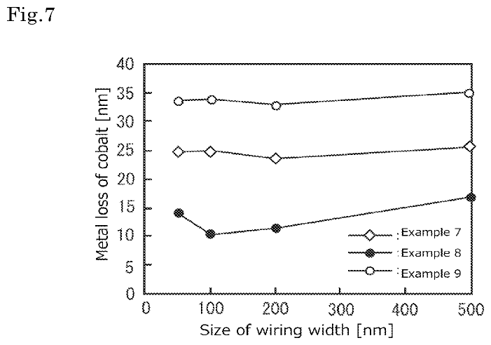

Using these treatment liquids 4 to 6, the cycle of immersing the test piece in the first pH/redox potential-adjusted water W1 for 1 minute and in the second pH/redox potential-adjusted water W2 for 1 minute, as in Example 1, was repeated 5 times. After that, the wiring portion of the Co pattern wafer was observed with XSEM, and the metal loss of cobalt was measured. The results are illustrated in FIG. 7.

As apparent from FIG. 7, when the metal loss of cobalt in the case of using an acid (formic acid) other than citric acid as the second pH/redox potential-adjusted water W2 was checked, the metal loss in Example 7 using citric acid was 25 nm/10 minutes as an average, while the metal loss in Example 8 was 9 nm/10 minutes as an average, and the metal loss in Example 9 was 34 nm/10 minutes as an average. In Example 8, the metal loss of cobalt was slightly different depending on differences in the line width, and the pattern loading occurred. In Example 9, there was almost no change in the metal loss of cobalt due to differences in the line width. From above, it was found that pattern loading did not occur. The pH of the second pH/redox potential-adjusted water W2 of Example 7 is about 2.8, the pH of the second pH/redox potential-adjusted water W2 of Example 8 is about 4.4, and the pH of the second pH/redox potential-adjusted water W2 of Example 9 is about 3.1, so it can be inferred that the pH of the second pH/redox potential-adjusted water W2 is important for extremely finely dissolving a predetermined amount of cobalt without causing the pattern loading.

As apparent from these Examples 1 to 9, according to the pH/redox potential-adjusted water production apparatus of the present invention, two types of treatment liquids having different pHs and/or different redox potentials can be produced to perform treatment of wafers. As a result, by variously combining the types of the pH adjusters and the redox potential adjusters and their additive amounts (pH, redox potential) in accordance with the wiring material and treatment time of semiconductors, it is possible to dissolve a predetermined amount of wiring metal in the wiring production step for semiconductors.

### DESCRIPTION OF REFERENCE NUMERALS

1 pH/redox potential-adjusted water production apparatus
2 Supply line
3 Platinum group metal-supporting resin column (hydrogen peroxide removal mechanism)
4 First adjusted water production line
41 pH adjuster tank
41A pH adjuster feeding line
41B Liquid supply mechanism
42 Redox potential adjuster tank
42A Redox potential adjuster feeding line
42B Liquid supply mechanism
43 First reservoir
44 On-off valve
47 First degassing membrane device
47A Vacuum pump
48 First gas dissolving membrane device
5 Second adjusted water production line
51 pH adjuster tank
51A pH adjuster feeding line
51B Liquid supply mechanism
52 Redox potential adjuster tank
52A Redox potential adjuster feeding line
52B Liquid supply mechanism
53 Second reservoir
54 On-off valve
55 Bypass line
56 On-off valve
57 Second degassing membrane device
57A Vacuum pump
58 Second gas dissolving membrane device
61 N₂ gas (inert gas) supply pipe
71 First gas dissolving membrane device
72 Second gas dissolving membrane device
W Ultrapure water
W1 First pH/redox potential-adjusted water
W2 Second pH/redox potential-adjusted water
UP Use point

1. A pH/redox potential-adjusted water production apparatus, comprising:
an ultrapure water supply line;
a first branched flow path;
a second branched flow path; and
an additive amount control mechanism;
wherein:
the ultrapure water supply line comprises a hydrogen peroxide removal mechanism;
the ultrapure water supply line branches into the first branched flow path and the second branch flow path downstream from the hydrogen peroxide removal mechanism;
each of the first branched flow path and the second branched flow path is provided with a pH adjusting mechanism configured to add pH adjuster into the respective flow path;
each of the first branched flow path and the second branched flow path is provided with a redox potential adjusting mechanism configured to add a redox potential adjuster into the respective flow path;
each of the first branched flow path and the second branched flow path is provided with an adjusted water quality monitoring mechanism configured to measure water quality in the respective flow path, the adjusted water quality monitoring mechanism being located downstream from the pH adjusting mechanism and the redox potential adjusting mechanism;
the additive amount control mechanism is configured to control an amount of the pH adjuster added to the respective flow path by the pH adjusting mechanism and an amount of the redox potential adjuster added to the respective flow path by the redox potential adjusting mechanism based on a measurement result obtained from the adjusted water quality monitoring mechanism; and
each of the first branched flow path and the second branched flow path comprises a reservoir configured to store pH/redox potential-adjusted water, the reservoir being located downstream from the pH adjusting mechanism and the redox potential adjusting mechanism;
wherein, in operation, different types of pH/redox potential-adjusted water can be supplied from respective flow paths.

2. The pH/redox potential-adjusted water production apparatus according to claim 1, wherein at least one of the first branched flow path and the second branched flow path comprises, at a location downstream from the pH adjusting mechanism and the redox potential adjusting mechanism, pH/redox potential-adjusted water having a pH of 9 to 13 and a redox potential of 0 V to 1.7 V.

3. The pH/redox potential-adjusted water production apparatus according to claim 1, wherein:
the pH adjusting mechanism contains at least one selected from the group consisting of ammonia, sodium hydroxide, potassium hydroxide, TMAH, hydrochloric acid, hydrofluoric acid, citric acid, formic acid, and carbon dioxide gas; and
the redox potential adjusting mechanism contains at least one selected from the group consisting of hydrogen peroxide, ozone gas, and oxygen gas.

4. The pH/redox potential-adjusted water production apparatus according to claim 1, wherein at least one of the pH adjusting mechanism and the redox potential adjusting mechanism is configured to add a liquid pH adjuster or liquid redox potential adjuster and comprises a pump or a pressurizing means that uses a closed tank and an inert gas.

5. The pH/redox potential-adjusted water production apparatus according to claim 1, wherein at least one of the pH adjusting mechanism and the redox potential adjusting mechanism is configured to add a gas pH adjuster or gas redox potential adjuster by gas dissolution and comprises a direct gas-liquid contactor with a gas-permeable membrane module or an ejector.

6. The pH/redox potential-adjusted water production apparatus according to claim 1, wherein the reservoir comprises an inert gas supply mechanism.

7. The pH/redox potential-adjusted water production apparatus according to claim 1, wherein at least one of the first branched flow path and the second branched flow path comprises, at a location downstream from the pH adjusting mechanism and the redox potential adjusting mechanism, pH/redox potential-adjusted water having a pH and redox potential suitable for cleaning a surface of a semiconductor material on which a transition metal is partially or entirely exposed.
